(19) United States
(12) Patent Application Publication
(10) Pub. No.: US 2024/0291442 A1
(43) Pub. Date: Aug. 29, 2024

(54) LIMITER CIRCUIT, MATCHING NETWORK, AND POWER AMPLIFIER CIRCUIT

(71) Applicant: Murata Manufacturing Co., Ltd., Kyoto (JP)

(72) Inventor: Shingo YANAGIHARA, Kyoto (JP)

(21) Appl. No.: 18/655,725

(22) Filed: May 6, 2024

Related U.S. Application Data
(63) Continuation of application No. PCT/JP2022/039568, filed on Oct. 24, 2022.

(30) Foreign Application Priority Data
Nov. 18, 2021 (JP) 2021-188038

(51) Int. Cl. H03F 1/52; H03F 1/56; H03F 3/21

(52) U.S. Cl. CPC H03F 1/52; H03F 1/565; H03F 3/21; H03F 2200/387; H03F 2200/426

(57) ABSTRACT

A limiter circuit includes: one or a plurality of first diodes having an anode electrically connected to a signal line through which a high-frequency signal passes, and a cathode electrically connected to a node, the plurality of first diodes being connected in series; a transistor having a source-drain path or an emitter-collector path electrically connected between a reference potential and the node, and a gate or a base to which a control voltage or a control current is input; and a first constant current source that outputs a first constant current to the node.

### CROSS REFERENCE TO RELATED APPLICATION

This is a continuation of International Application No. PCT/JP2022/039568 filed on Oct. 24, 2022 which claims priority from Japanese Patent Application No. 2021-188038 filed on Nov. 18, 2021. The contents of these applications are incorporated herein by reference in their entireties.

### BACKGROUND ART

### Technical Field

The present disclosure relates to a limiter circuit, a matching network, and a power amplifier circuit.

The following Patent Document 1 discloses an active clamping circuit including a plurality of diodes provided in a forward direction toward a ground to keep excessive power from damaging an amplifier.
Patent Document 1: U.S. Pat. No. 6,580,321

### BRIEF SUMMARY

In the active clamping circuit disclosed in Patent Document 1, however, sufficient control of adjusting the amplitude of a high-frequency signal (clipping control) is unable to be achieved.

The present disclosure has been made in view of the above to enable control of adjusting the amplitude of a high-frequency signal to be achieved.

A limiter circuit according to one aspect of the present disclosure includes: one or a plurality of first diodes having an anode electrically connected to a signal line through which a high-frequency signal passes, and a cathode electrically connected to a node, the plurality of first diodes being connected in series; a transistor having a source-drain path or an emitter-collector path electrically connected between a reference potential and the node, and a gate or a base to which a control voltage or a control current is input; and a first constant current source that outputs a first constant current to the node.

A matching network according to one aspect of the present disclosure provides impedance matching between an output impedance of a first circuit that amplifies a high-frequency signal and an input impedance of a second circuit that amplifies the high-frequency signal amplified by the first circuit. The matching network includes the above-described limiter circuit.

A power amplifier circuit according to one aspect of the present disclosure includes: a first circuit that amplifies a high-frequency signal; a second circuit that amplifies the high-frequency signal amplified by the first circuit; and a matching network that provides impedance matching between an output impedance of the first circuit and an input impedance of the second circuit. The matching network includes the above-described limiter circuit.

The present disclosure enables control of adjusting the amplitude of a high-frequency signal to be achieved.

### BRIEF DESCRIPTION OF THE DRAWINGS

FIG. 1 is a diagram illustrating a configuration of a power amplifier circuit according to a first embodiment.

FIG. 2 is a diagram illustrating a configuration of a bias circuit of the power amplifier circuit according to the first embodiment.

FIG. 3 is a diagram illustrating a configuration of a limiter circuit of the power amplifier circuit according to the first embodiment.

FIG. 4 is a graph illustrating an example of control performed by the limiter circuit of the power amplifier circuit according to the first embodiment.

FIG. 5 is a graph illustrating an example of control performed by the limiter circuit of the power amplifier circuit according to the first embodiment.

FIG. 6 is a graph illustrating another example of control performed by the limiter circuit of the power amplifier circuit according to the first embodiment.

FIG. 7 is a graph illustrating another example of control performed by the limiter circuit of the power amplifier circuit according to the first embodiment.

FIG. 8 is a graph illustrating circuit simulation results of the power amplifier circuit according to the first embodiment.

FIG. 9 is a graph illustrating circuit simulation results of the power amplifier circuit according to the first embodiment.

FIG. 10 is a diagram illustrating a configuration of a limiter circuit according to a second embodiment.

FIG. 11 is a graph illustrating an example of control performed by the limiter circuit according to the second embodiment.

FIG. 12 is a graph illustrating an example of control performed by the limiter circuit according to the second embodiment.

FIG. 13 is a graph illustrating an example of control performed by the limiter circuit according to the second embodiment.

FIG. 14 is a diagram illustrating a configuration of a limiter circuit according to a third embodiment.

FIG. 15 is a diagram illustrating a configuration of a limiter circuit according to a fourth embodiment.

FIG. 16 is a diagram illustrating a configuration of a limiter circuit according to a fifth embodiment.

FIG. 17 is a diagram illustrating a configuration of a limiter circuit according to a reference example.

### DETAILED DESCRIPTION

An embodiment of a limiter circuit, a matching network, and a power amplifier circuit according to the present disclosure will be described in detail below with reference to the drawings. Note that the present disclosure is not to be limited by this embodiment. Individual embodiments are illustrative, and it goes without necessarily saying that configurations described in different embodiments can be partially replaced or combined.

### First Embodiment

### (Entire Configuration)

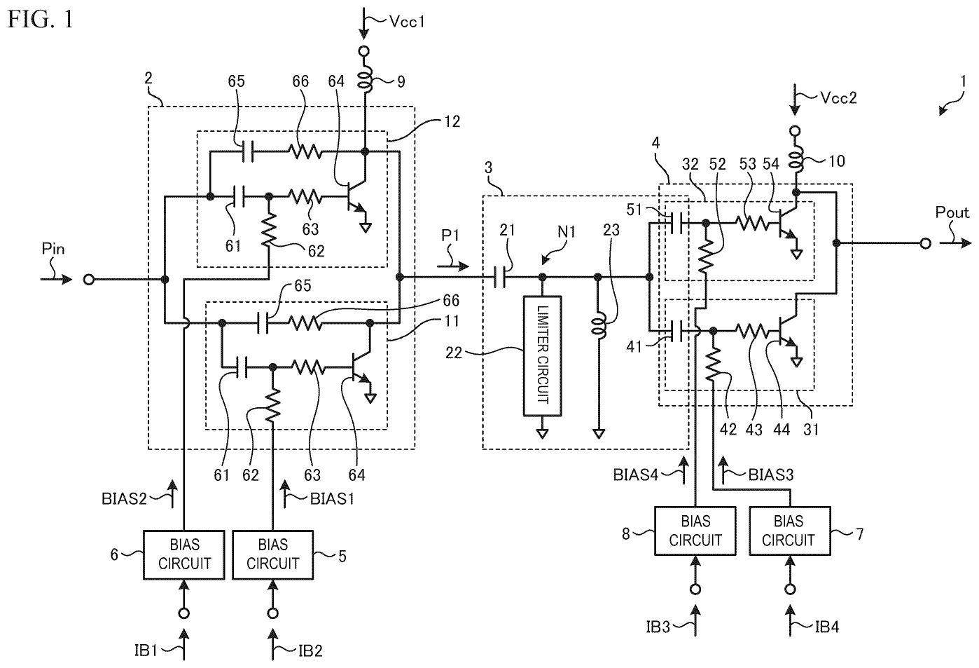

FIG. 1 is a diagram illustrating a configuration of a power amplifier circuit according to a first embodiment. A power amplifier circuit 1 amplifies a high-frequency signal Pin and outputs a high-frequency signal Pout.

The power amplifier circuit 1 has an amplification operation at relatively low first output power (hereinafter referred to as “low power mode” in some cases), and an amplification operation at relatively high second output power (hereinafter referred to as “high power mode” in some cases).

Although, in the first embodiment, the power amplifier circuit 1 has two modes, the present disclosure is not limited to this. The power amplifier circuit 1 may have only one mode.

The power amplifier circuit 1 includes a first circuit 2 at a driver stage (first stage), a matching network 3, a second circuit 4 at a power stage (final stage), and bias circuits 5 to 8.

Although, in the first embodiment, the power amplifier circuit 1 includes two stages of amplifier circuits, the present disclosure is not limited to this. The power amplifier circuit 1 may include three or more stages of amplifier circuits.

The first circuit 2 includes amplifiers 11 and 12.

Although, in the first embodiment, the first circuit 2 includes two amplifiers, the present disclosure is not limited to this. The first circuit 2 may include one or three or more amplifiers.

The amplifiers 11 and 12 are electrically connected to a power supply potential Vcc1 via a choke coil 9. The amplifier 11 operates both in the low power mode and the high power mode. The amplifier 12 operates in the high power mode.

The amplifiers 11 and 12 amplify a high-frequency signal Pin and output a high-frequency signal P1 from a collector to the matching network 3.

The amplifier 11 includes capacitors 61 and 65, resistors 62, 63, and 66, and a transistor 64.

Note that a circuit configuration of the amplifier 12 is similar to a circuit configuration of the amplifier 11, and a description thereof is therefore omitted.

Although, in the present disclosure, each of transistors is a bipolar transistor, the present disclosure is not limited to this. Although, as an example of the bipolar transistor, a Heterojunction Bipolar Transistor (HBT) is given, the present disclosure is not limited to this. The transistor may be, for example, a Field Effect Transistor (FET). The transistor may be a multi-finger transistor including a plurality of unit transistors electrically connected in parallel. A unit transistor refers to a minimum component constituting the transistor.

A high-frequency signal Pin is input to one end of the capacitor 61. The capacitor 61 is a DC cut capacitor that cuts off a direct-current component of the high-frequency signal Pin.

One end of the resistor 63 is electrically connected to the other end of the capacitor 61. The other end of the resistor 63 is electrically connected to a base of the transistor 64.

A bias current BIAS1 is input from the bias circuit 5 (see FIG. 1) to one end of the resistor 62. The other end of the resistor 62 is electrically connected to the one end of the resistor 63.

An emitter of the transistor 64 is electrically connected to a reference potential. Although, as an example of the reference potential, a ground potential is given, the present disclosure is not limited to this.

The bias current BIAS1 is input to the base of the transistor 64 via the resistors 62 and 63. Furthermore, the high-frequency signal Pin is input to the base of the transistor 64 via the capacitor 61 and the resistor 63.

A collector of the transistor 64 is electrically connected to the power supply potential Vcc1 via the choke coil 9.

The capacitor 65 and the resistor 66 are connected in series between the collector of the transistor 64 and the one end of the capacitor 61, and negative feedback is provided.

A bias current IB2 is input from an external current source to the bias circuit 5. The bias circuit 5 outputs a bias current BIAS1 to the amplifier 11 in accordance with the bias current IB2. The bias circuit 5 outputs a bias current BIAS1 both in the low power mode and the high power mode.

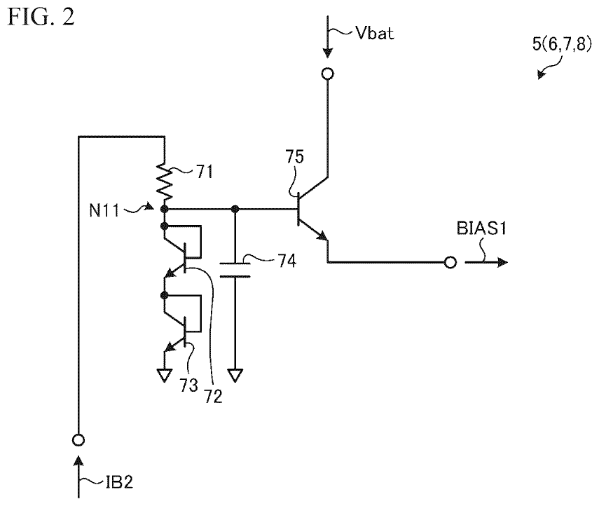

FIG. 2 is a diagram illustrating a configuration of a bias circuit of the power amplifier circuit according to the first embodiment.

Note that circuit configurations of the bias circuits 6, 7, and 8 are similar to a circuit configuration of the bias circuit 5, and a description thereof is therefore omitted.

The bias circuit 5 includes a resistor 71, transistors 72, 73, and 75, and a capacitor 74.

A bias current IB2 is input to one end of the resistor 71. The other end of the resistor 71 is electrically connected to a node N11.

A collector and a base of the transistor 72 are electrically connected to the node N11. That is, the transistor 72 is diode-connected. An emitter of the transistor 72 is electrically connected to a collector and a base of the transistor 73. That is, the transistor 73 is diode-connected. An emitter of the transistor 73 is electrically connected to the reference potential.

The transistors 72 and 73 generate a fixed voltage. A voltage generated by the transistors 72 and 73 is a voltage at the node N11.

One end of the capacitor 74 is electrically connected to the node N11. The other end of the capacitor 74 is electrically connected to the reference potential. The capacitor 74 stabilizes the voltage at the node N11.

A collector of the transistor 75 is electrically connected to a power supply potential Vbat. A base of the transistor 75 is electrically connected to the node N11. An emitter of the transistor 75 is electrically connected to the one end of the resistor 62 (see FIG. 1). That is, the transistor 75 and the resistor 62 are connected so as to establish an emitter-follower connection. The transistor 75 outputs a bias current BIAS1 based on the voltage at the node N11 from the emitter to the one end of the resistor 62.

Referring back to FIG. 1, a bias current IB1 is input from an external current source to the bias circuit 6. The bias circuit 6 outputs a bias current BIAS2 to the amplifier 12 in accordance with the bias current IB1. The bias circuit 6 outputs a bias current BIAS2 in the high power mode.

The matching network 3 provides impedance matching between an output impedance of the first circuit 2 and an input impedance of the second circuit 4.

The matching network 3 includes a capacitor 21, a limiter circuit 22, and an inductor 23. Incidentally, it can be considered that the matching network 3 includes capacitors 41 and 51 (to be described).

One end of the capacitor 21 is electrically connected to output terminals of the amplifiers 11 and 12. The other end of the capacitor 21 is electrically connected to a node N1.

One end of the limiter circuit 22 is electrically connected to the node N1. The other end of the limiter circuit 22 is electrically connected to the reference potential.

The node N1 corresponds to an example of “first node” in the present disclosure.

When a voltage of a high-frequency signal P1 that passes through the node N1 is above an upper limit voltage Vmax, the limiter circuit 22 limits the voltage of the high-frequency signal P1 to the upper limit voltage Vmax. Furthermore, when the voltage of the high-frequency signal P1 is below a lower limit voltage Vmin, the limiter circuit 22 limits the voltage of the high-frequency signal P1 to the lower limit voltage Vmin.

A configuration of the limiter circuit 22 will be described later.

One end of the inductor 23 is electrically connected to the node N1. The other end of the inductor 23 is electrically connected to the reference potential.

Note that a configuration of the matching network 3 illustrated in FIG. 1 is an example, and the present disclosure is not limited to this. Various circuit configurations are applicable to the matching network 3.

The second circuit 4 includes amplifiers 31 and 32. The amplifier 31 operates both in the low power mode and the high power mode. The amplifier 32 operates in the high power mode.

The amplifiers 31 and 32 amplify the high-frequency signal P1 and output a high-frequency signal Pout.

The amplifier 31 includes the capacitor 41, resistors 42 and 43, and a transistor 44.

One end of the capacitor 41 is electrically connected to the node N1. The capacitor 41 is a DC cut capacitor that cuts off a direct-current component of the high-frequency signal P1.

As described above, it can be considered that the capacitor 41 is included in the matching network 3.

One end of the resistor 43 is electrically connected to the other end of the capacitor 41. The other end of the resistor 43 is electrically connected to a base of the transistor 44.

A bias current BIAS3 is input to one end of the resistor 42. The other end of the resistor 42 is electrically connected to the one end of the resistor 43.

An emitter of the transistor 44 is electrically connected to the reference potential. The bias current BIAS3 is input from the bias circuit 7 to the base of the transistor 44 via the resistors 42 and 43. Furthermore, the high-frequency signal P1 is input to the base of the transistor 44 via the matching network 3, the capacitor 41, and the resistor 43.

A collector of the transistor 44 is electrically connected to a power-supply potential Vcc2 via a choke coil 10.

The transistor 44 amplifies the high-frequency signal P1 and outputs a high-frequency signal Pout from the collector.

The amplifier 32 includes the capacitor 51, resistors 52 and 53, and a transistor 54.

A connection relationship among the capacitor 51, the resistors 52 and 53, and the transistor 54 is similar to a connection relationship among the capacitor 41, the resistors 42 and 43, and transistor 44, and a description thereof is therefore omitted.

A bias current IB4 is input from an external current source to the bias circuit 7. The bias circuit 7 outputs a bias current BIAS3 to the amplifier 31 in accordance with the bias current IB4. The bias circuit 7 outputs a bias current BIAS3 both in the low power mode and the high power mode.

A bias current IB3 is input from an external current source to the bias circuit 8. The bias circuit 8 outputs a bias current BIAS4 to the amplifier 32 in accordance with the bias current IB3. The bias circuit 8 outputs a bias current BIAS4 in the high power mode.

### (Limiter Circuit)

When the voltage of the high-frequency signal P1 that passes through the node N1 is above the upper limit voltage Vmax, the limiter circuit 22 limits the voltage of the high-frequency signal P1 to the upper limit voltage Vmax. Furthermore, when the voltage of the high-frequency signal P1 is below the lower limit voltage Vmin, the limiter circuit 22 limits the voltage of the high-frequency signal P1 to the lower limit voltage Vmin.

Thus, the limiter circuit 22 can keep the second circuit 4 from being subjected to excessive input and can keep the second circuit 4 from being damaged.

### [Configuration]

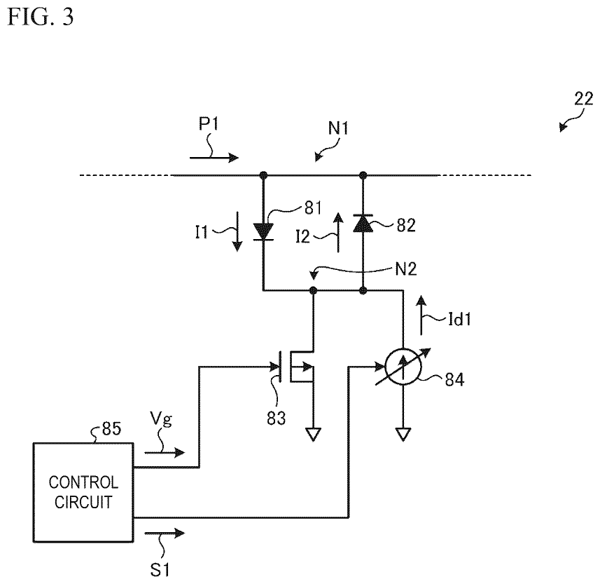

FIG. 3 is a diagram illustrating a configuration of the limiter circuit of the power amplifier circuit according to the first embodiment.

The limiter circuit 22 includes diodes 81 and 82, a transistor 83, a constant current source 84, and a control circuit 85.

The diode 81 corresponds to an example of “first diode” in the present disclosure. The diode 82 corresponds to an example of “second diode” in the present disclosure. The constant current source 84 corresponds to an example of “first constant current source” in the present disclosure. The control circuit 85 corresponds to an example of “control circuit” in the present disclosure.

Although, in the first embodiment, the transistor 83 is an N-channel FET, the present disclosure is not limited to this. The transistor 83 may be, for example, a P-channel FET, or a bipolar transistor.

An anode of the diode 81 is electrically connected to the node N1. A cathode of the diode 81 is electrically connected to a node N2. Hereinafter, a direction from the node N1 toward the node N2 is referred to as a forward direction or a first direction in some cases.

The node N2 corresponds to an example of “second node” in the present disclosure.

Although, in the first embodiment, a diode in the forward direction is one diode 81, the present disclosure is not limited to this. The diode in the forward direction may be two or more diodes connected in series.

An anode of the diode 82 is electrically connected to the node N2. A cathode of the diode 82 is electrically connected to the node N1. Hereinafter, a direction from the node N2 toward the node N1 is referred to as a reverse direction or a second direction in some cases.

Although, in the first embodiment, a diode in the reverse direction is one diode 82, the present disclosure is not limited to this. The diode in the reverse direction may be two or more diodes connected in series.

A source (or emitter) of the transistor 83 is electrically connected to the reference potential. A drain (or collector) of the transistor 83 is electrically connected to the node N2. A control voltage Vg is input from the control circuit 85 to a gate (or base) of the transistor 83.

Note that, in the first embodiment, the transistor 83 operates in accordance with the control voltage Vg of not less than a threshold voltage of the gate of the transistor 83. However, the present disclosure is not limited to this. When the voltage of the high-frequency signal P1 does not have to be limited, it is appropriate that the control voltage Vg is less than the threshold voltage to bring the transistor 83 into a cut-off region. Thus, the limiter circuit 22 does not operate, and a voltage limit placed on the high-frequency signal P1 by the limiter circuit 22 is lifted.

Furthermore, although, in the first embodiment, the control circuit 85 outputs the control voltage Vg to the gate of the transistor 83, the present disclosure is not limited to this. A predetermined constant voltage may be input to the gate of the transistor 83.

Furthermore, when the transistor 83 is a bipolar transistor, the control circuit 85 may output a control current to a base of the bipolar transistor. Furthermore, a predetermined constant current may be input to the base of the bipolar transistor.

One end of the constant current source 84 is electrically connected to the reference potential. The other end of the constant current source 84 is electrically connected to the node N2. The constant current source 84 outputs, to the node N2, a constant current Id1 based on a control signal S1 input from the control circuit 85.

The control signal S1 corresponds to an example of “first control signal” in the present disclosure. The constant current Id1 corresponds to an example of “first constant current” in the present disclosure.

Note that, although, in the first embodiment, the constant current source 84 outputs the constant current Id1 based on the control signal S1, the present disclosure is not limited to this. The constant current source 84 may output a predetermined constant current Id1.

A maximum value Ids_max of a drain current of the transistor 83 is determined in accordance with the control voltage Vg. Although an example is given in which the constant current Id1 is less than the maximum value Ids_max of the drain current of the transistor 83, the present disclosure is not limited to this.

When the high-frequency signal P1 is feeble, or under no-signal conditions, the diodes 81 and 82 enter a cut-off state. Hence, the drain current of the transistor 83 is the constant current Id1. At this time, a voltage at the node N2 is a drain-source voltage Vds of the transistor 83, that is, the product of an on resistance (impedance) of the transistor 83 and the constant current Id1.

The on resistance of the transistor 83 is relatively large when the control voltage Vg is relatively low, and the on resistance is relatively small when the control voltage Vg is relatively high. Hence, when the control voltage Vg is adjusted, the voltage at the node N2 can be adjusted. Furthermore, when the constant current Id1 is adjusted, the voltage at the node N2 can also be adjusted.

The upper limit voltage Vmax is the sum of a threshold voltage Vth1 of the diode 81 and the drain-source voltage Vds of the transistor 83. The lower limit voltage Vmin is the sum of a source-drain voltage Vsd of the transistor 83 and a threshold voltage-Vth2 of the diode 82.

Hence, when the control voltage Vg is adjusted, the upper limit voltage Vmax and the lower limit voltage Vmin can be adjusted. Furthermore, when the constant current Id1 is adjusted, the upper limit voltage Vmax and the lower limit voltage Vmin can also be adjusted.

When the voltage of the high-frequency signal P1 is above the upper limit voltage Vmax, the diode 81 enters a conductive state. Thus, a current I1 flows in a direction from the node N1 toward the reference potential. At this time, a maximum value I1_max of the current I1 that flows through the diode 81 is the difference between the maximum value Ids_max of the drain current of the transistor 83 and the constant current Id1.

Hence, when the constant current Id1 is adjusted, the maximum value I1_max of the current I1 can be adjusted.

When the voltage of the high-frequency signal P1 is below the lower limit voltage Vmin, the diode 82 enters a conductive state. Thus, the constant current Id1 flows to the diode 82, and a current also flows in a direction from the reference potential toward the node N1. At this time, a maximum value I2_max of a current I2 that flows through the diode 82 is the sum of the maximum value Ids_max of the drain current of the transistor 83 and the constant current Id1.

Hence, when the constant current Id1 is adjusted, the maximum value I2_max of the current I2 can be adjusted.

It can be considered that the upper limit voltage Vmax and the lower limit voltage Vmin of the high-frequency signal P1, the maximum value I1_max of the current I1, and the maximum value I2_max of the current I2 are roughly adjusted by using the control voltage Vg and are finely adjusted by using the control signal S1.

The control circuit 85 outputs the control voltage Vg and the control signal S1 in accordance with the power supply potential Vcc1, a temperature of the transistor 64 (see FIG. 1), or a current amplification factor β of the transistor 64.

Note that, although, in the first embodiment, the control circuit 85 outputs the control voltage Vg and the control signal S1 in accordance with the power supply potential Vcc1, the temperature of the transistor 64 (see FIG. 1), or the current amplification factor β of the transistor 64, the present disclosure is not limited to this. The control circuit 85 may output the control voltage Vg and the control signal S1 in accordance with, in addition to these physical quantities or in place of these physical quantities, another physical quantity. Although, as an example of the other physical quantity, a physical quantity representing a state of the transistor 64 is given, the present disclosure is not limited to this.

The power supply potential Vcc1 can be measured by a circuit that detects a voltage. The temperature of the transistor 64 can be measured by a circuit that detects a temperature. The current amplification factor β of the transistor 64 can be measured by providing a replica transistor of the transistor 64 and measuring a base current and a collector current of the replica transistor.

### [Example of Control]

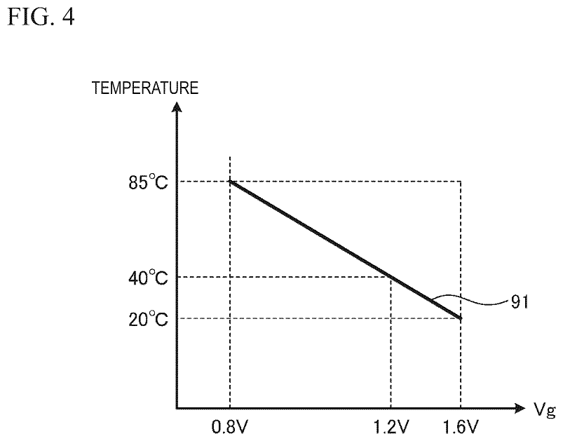

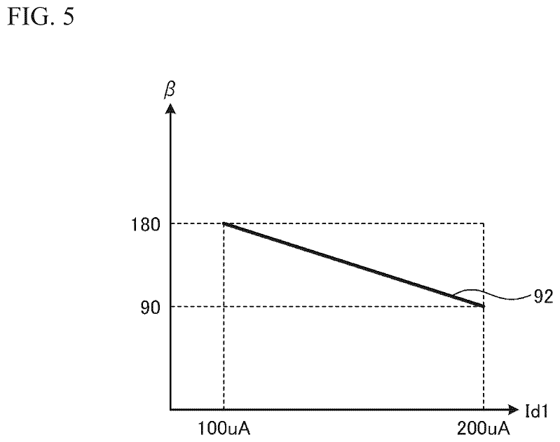

FIGS. 4 and 5 are graphs illustrating an example of control performed by the limiter circuit of the power amplifier circuit according to the first embodiment.

In general, the gain of a transistor increases as the temperature of the transistor decreases, and the gain of the transistor decreases as the temperature of the transistor increases. Thus, FIG. 4 illustrates an example of control performed by the control circuit 85 in which the high-frequency signal P1 is limited to a large extent (the upper limit voltage Vmax is reduced and the lower limit voltage Vmin is increased) when the temperature of the transistor 64 (see FIG. 1) is relatively low and in which the high-frequency signal P1 is limited to a small extent (the upper limit voltage Vmax is increased and the lower limit voltage Vmin is reduced) when the temperature of the transistor 64 is relatively high.

FIG. 4 is a graph illustrating an example of the relationship between the temperature of the transistor 64 and the control voltage Vg. As indicated by a line 91, an example is illustrated in which the control circuit 85 outputs the control voltage Vg of 0.8 V (volts) when the temperature of the transistor 64 is 85° C. Furthermore, an example is illustrated in which the control circuit 85 outputs the control voltage Vg of 1.2 V when the temperature of the transistor 64 is 40° C. Furthermore, an example is illustrated in which the control circuit 85 outputs the control voltage Vg of 1.6 V when the temperature of the transistor 64 is 20° C.

The larger the current amplification factor β of the transistor 64 is, the more likely the second circuit 4 is to be subjected to excessive input, and the smaller the current amplification factor β is, the less likely the second circuit 4 is to be subjected to excessive input. Thus, FIG. 5 illustrates an example of control performed by the control circuit 85 in which the high-frequency signal P1 is limited to a large extent (the upper limit voltage Vmax is reduced and the lower limit voltage Vmin is increased) when the current amplification factor β of the transistor 64 is relatively large and in which the high-frequency signal P1 is limited to a small extent (the upper limit voltage Vmax is increased and the lower limit voltage Vmin is reduced) when the current amplification factor β of the transistor 64 is relatively small.

FIG. 5 is a graph illustrating an example of the relationship between the current amplification factor β of the transistor 64 and the constant current Id1. As indicated by a line 92, an example is illustrated in which the control circuit 85 outputs the control signal S1 that causes the constant current source 84 to output the constant current Id1 of 100 μA (microamperes) when the current amplification factor β of the transistor 64 is 180. Furthermore, an example is illustrated in which the control circuit 85 outputs the control signal S1 that causes the constant current source 84 to output the constant current Id1 of 200 μA when the current amplification factor β of the transistor 64 is 90.

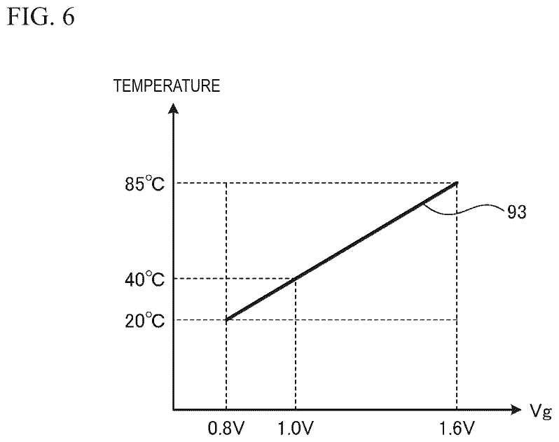

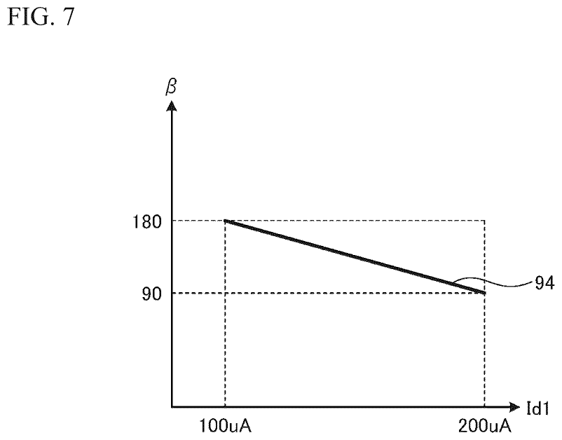

FIGS. 6 and 7 are graphs illustrating another example of control performed by the limiter circuit of the power amplifier circuit according to the first embodiment.

FIGS. 6 and 7 illustrate an example of control performed by the control circuit 85 in which the high-frequency signal P1 is limited to a small extent (the upper limit voltage Vmax is increased and the lower limit voltage Vmin is reduced) when the temperature of the transistor 64 (see FIG. 1) is relatively low and in which the high-frequency signal P1 is limited to a large extent when the temperature of the transistor 64 is relatively high.

FIG. 6 is a graph illustrating an example of the relationship between the temperature of the transistor 64 and the control voltage Vg. As indicated by a line 93, an example is illustrated in which the control circuit 85 outputs the control voltage Vg of 0.8 V when the temperature of the transistor 64 is 20° C. Furthermore, an example is illustrated in which the control circuit 85 outputs the control voltage Vg of 1.0 V when the temperature of the transistor 64 is 40° C. Furthermore, an example is illustrated in which the control circuit 85 outputs the control voltage Vg of 1.6 V when the temperature of the transistor 64 is 85° C.

FIG. 7 is a graph illustrating an example of the relationship between the current amplification factor β of the transistor 64 and the constant current Id1. As indicated by a line 94, an example is illustrated in which the control circuit 85 outputs the control signal S1 that causes the constant current source 84 to output the constant current Id1 of 100 μA when the current amplification factor β of the transistor 64 is 180. Furthermore, an example is illustrated in which the control circuit 85 outputs the control signal S1 that causes the constant current source 84 to output the constant current Id1 of 200 μA when the current amplification factor β of the transistor 64 is 90.

Note that, although, in the above-described examples of control, the control circuit 85 controls the control voltage Vg in accordance with the temperature of the transistor 64, the present disclosure is not limited to this. The control circuit 85 may control the constant current Id1 in accordance with the temperature of the transistor 64.

Furthermore, although, in the above-described examples of control, the control circuit 85 controls the constant current Id1 in accordance with the current amplification factor β of the transistor 64, the present disclosure is not limited to this. The control circuit 85 may control the control voltage Vg in accordance with the current amplification factor β of the transistor 64.

Furthermore, although, in the above-described examples of control, the control circuit 85 controls the control voltage Vg in accordance with the temperature of the transistor 64, the present disclosure is not limited to this. The control circuit 85 may control the control voltage Vg in accordance with the power supply potential Vcc1.

In general, the output power of a transistor increases as a power supply potential increases, and the output power of the transistor decreases as the power supply potential decreases. Thus, although an example is given in which the control circuit 85 relatively reduces the control voltage Vg when the power supply potential Vcc1 of the transistor 64 is relatively low and in which the control circuit 85 relatively increases the control voltage Vg when the power supply potential Vcc1 is relatively high, the present disclosure is not limited to this.

Furthermore, although, in the above-described examples of control, the control circuit 85 controls the constant current Id1 in accordance with the current amplification factor β of the transistor 64, the present disclosure is not limited to this. The control circuit 85 may control the constant current Id1 in accordance with the power supply potential Vcc1.

Although an example is given in which the control circuit 85 controls the constant current Id1 to a small extent when the power supply potential Vcc1 is relatively high and in which the control circuit 85 controls the constant current Id1 to a large extent when the power supply potential Vcc1 is relatively low, the present disclosure is not limited to this.

### [Effects]

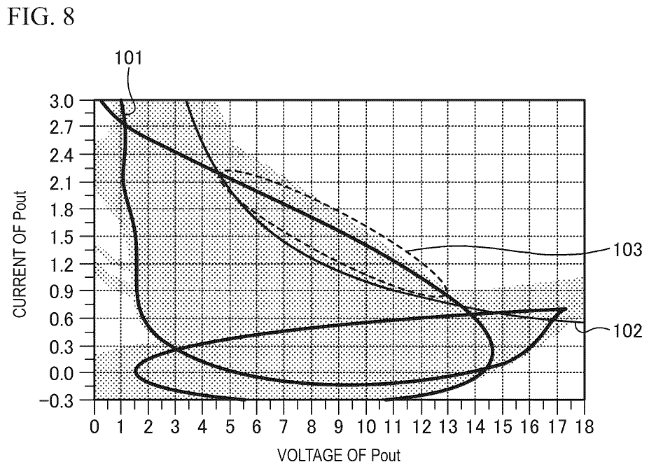

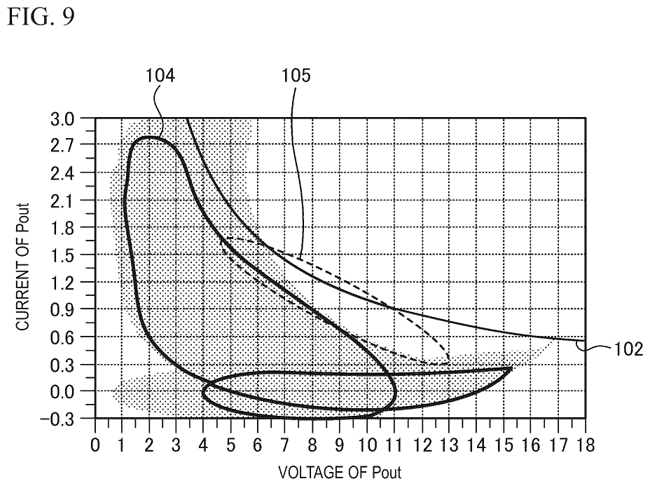

FIGS. 8 and 9 are graphs illustrating circuit simulation results of the power amplifier circuit according to the first embodiment.

FIG. 8 is a graph illustrating a load line (Lissajous waveform for the current and voltage of the high-frequency signal Pout) of the transistors 44 and 54 (see FIG. 1) exhibited when the control voltage Vg is 0 V and a voltage limit placed on the high-frequency signal P1 by the limiter circuit 22 is lifted.

FIG. 9 is a graph illustrating a load line (Lissajous waveform for the current and voltage of the high-frequency signal Pout) of the transistors 44 and 54 exhibited when the voltage of the high-frequency signal P1 is limited by the limiter circuit 22.

In FIGS. 8 and 9, a plurality of waveforms exhibited when the impedance of a load connected to a stage subsequent to the power amplifier circuit 1 is changed are shaded.

Referring to FIG. 8, a waveform 101 is an example of a load line of the transistors 44 and 54. A line 102 is a constant power line of 10 W (watts).

In a region 103, the waveform 101 is present on an upper side of the graph than the line 102, and the second circuit 4 is in an excessive output power state (due to excessive input power).

Referring to FIG. 9, a waveform 104 is an example of a load line of the transistors 44 and 54.

In a region 105, the waveform 104 is present on a lower side of the graph than the line 102, and the second circuit 4 is not in an excessive output power state (due to excessive input power).

Thus, the limiter circuit 22 can keep the second circuit 4 from being subjected to excessive input power. As a result, the limiter circuit 22 can keep the second circuit 4 from being damaged.

Furthermore, the limiter circuit 22 can perform control of adjusting the upper limit voltage Vmax and the lower limit voltage Vmin of the high-frequency signal P1, the maximum value I1_max of the current I1, and the maximum value I2_max of the current I2 in accordance with the power supply potential Vcc1, the temperature of the transistor 64 (see FIG. 1), or the current amplification factor β of the transistor 64.

### Second Embodiment

Of components of a limiter circuit according to a second embodiment, components that are the same as those in the first embodiment are denoted by the same reference signs, and a description thereof is omitted.

### [Configuration]

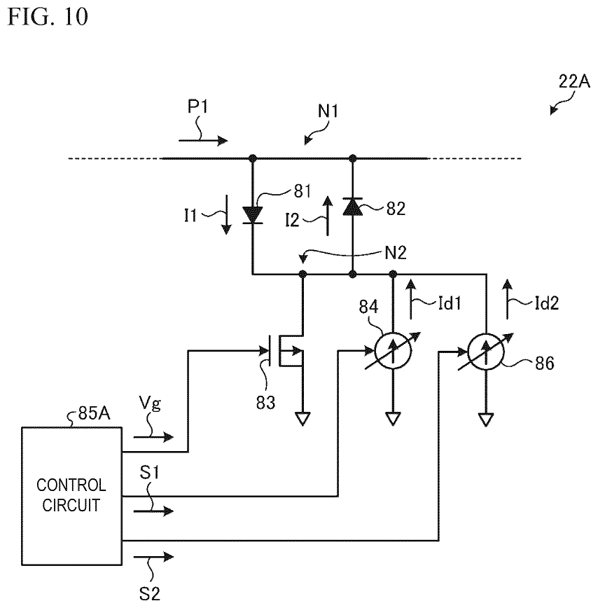

FIG. 10 is a diagram illustrating a configuration of a limiter circuit according to the second embodiment.

In comparison with the limiter circuit 22 (see FIG. 3), a limiter circuit 22A further includes a constant current source 86. Furthermore, in comparison with the limiter circuit 22, the limiter circuit 22A includes a control circuit 85A in place of the control circuit 85.

The constant current source 86 corresponds to an example of “second constant current source” in the present disclosure. The control circuit 85A corresponds to an example of “control circuit” in the present disclosure.

One end of the constant current source 86 is electrically connected to the reference potential. The other end of the constant current source 86 is electrically connected to the node N2. The constant current source 86 outputs, to the node N2, a constant current Id2 based on a control signal S2 input from the control circuit 85A.

The control signal S2 corresponds to an example of “second control signal” in the present disclosure. The constant current Id2 corresponds to an example of “second constant current” in the present disclosure.

Note that, although, in the second embodiment, the constant current source 86 outputs the constant current Id2 based on the control signal S2, the present disclosure is not limited to this. The constant current source 86 may output a predetermined constant current Id2.

The maximum value Ids_max of the drain current of the transistor 83 is determined in accordance with the control voltage Vg. Although an example is given in which the sum of the constant current Id1 and the constant current Id2 is less than the maximum value Ids_max of the drain current of the transistor 83, the present disclosure is not limited to this.

When the high-frequency signal P1 is feeble, or under no-signal conditions, the diodes 81 and 82 enter a cut-off state. Hence, the drain current of the transistor 83 is the sum of the constant current Id1 and the constant current Id2. At this time, the voltage at the node N2 is the drain-source voltage Vds of the transistor 83, that is, the product of the on resistance (impedance) of the transistor 83 and the sum of the constant current Id1 and the constant current Id2.

When the voltage of the high-frequency signal P1 is above the upper limit voltage Vmax, the diode 81 enters a conductive state. Thus, a current flows in the direction from the node N1 toward the reference potential. At this time, the maximum value I1_max of the current I1 that flows through the diode 81 is the difference between the maximum value Ids_max of the drain current of the transistor 83 and the sum of the constant current Id1 and the constant current Id2.

Hence, when the constant currents Id1 and Id2 are adjusted, the maximum value I1_max of the current I1 can be adjusted.

When the voltage of the high-frequency signal P1 is below the lower limit voltage Vmin, the diode 82 enters a conductive state. Thus, the constant currents Id1 and Id2 flow to the diode 82, and a current also flows in the direction from the reference potential toward the node N1. At this time, the maximum value I2_max of the current I2 that flows through the diode 82 is the sum of the maximum value Ids_max of the drain current of the transistor 83, the constant current Id1, and the constant current Id2.

Hence, when the constant currents Id1 and Id2 are adjusted, the maximum value I2_max of the current I2 can be adjusted.

It can be considered that the upper limit voltage Vmax and the lower limit voltage Vmin of the high-frequency signal P1, the maximum value I1_max of the current I1, and the maximum value I2_max of the current I2 are roughly adjusted by using the control voltage Vg and are finely adjusted by using the control signals S1 and S2.

The control circuit 85A outputs the control voltage Vg and the control signals S1 and S2 in accordance with the power supply potential Vcc1, the temperature of the transistor 64 (see FIG. 1), and the current amplification factor β of the transistor 64.

### [Example of Control]

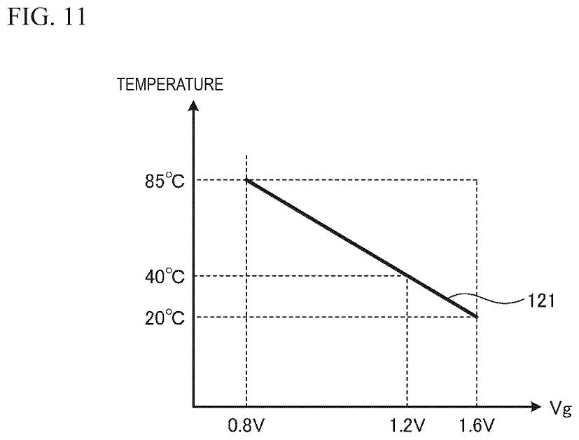

FIGS. 11 to 13 are graphs illustrating an example of control performed by the limiter circuit according to the second embodiment.

FIG. 11 is a graph illustrating an example of the relationship between the temperature of the transistor 64 (see FIG. 1) and the control voltage Vg. As indicated by a line 121, an example is illustrated in which the control circuit 85A outputs the control voltage Vg of 0.8 V when the temperature of the transistor 64 is 85° C. Furthermore, an example is illustrated in which the control circuit 85A outputs the control voltage Vg of 1.2 V when the temperature of the transistor 64 is 40° C. Furthermore, an example is illustrated in which the control circuit 85A outputs the control voltage Vg of 1.6 V when the temperature of the transistor 64 is 20° C.

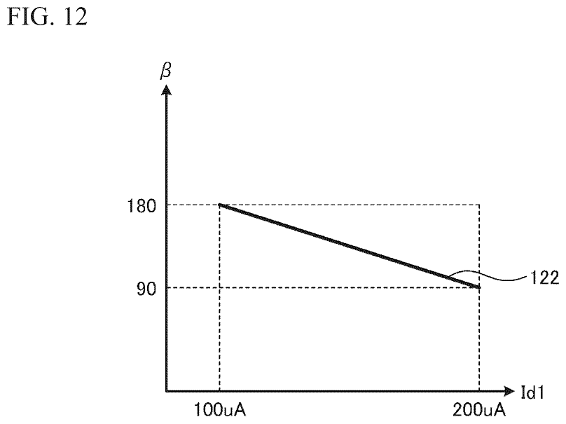

FIG. 12 is a graph illustrating an example of the relationship between the current amplification factor β of the transistor 64 and the constant current Id1. As indicated by a line 122, an example is illustrated in which the control circuit 85A outputs the control signal S1 that causes the constant current source 84 to output the constant current Id1 of 100 μA when the current amplification factor β of the transistor 64 is 180. Furthermore, an example is illustrated in which the control circuit 85A outputs the control signal S1 that causes the constant current source 84 to output the constant current Id1 of 200 μA when the current amplification factor β of the transistor 64 is 90.

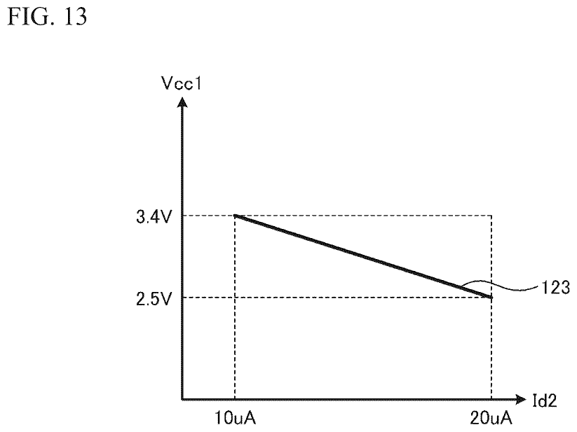

FIG. 13 is a graph illustrating an example of the relationship between the power supply potential Vcc1 of the transistor 64 and the constant current Id2. As indicated by a line 123, an example is illustrated in which the control circuit 85A outputs the control signal S2 that causes the constant current source 86 to output the constant current Id2 of 10 μA when the power supply potential Vcc1 of the transistor 64 is 3.4 V. Furthermore, an example is illustrated in which the control circuit 85A outputs the control signal S2 that causes the constant current source 86 to output the constant current Id2 of 20 μA when the power supply potential Vcc1 of the transistor 64 is 2.5 V.

Note that, although, in the above-described examples of control, the control circuit 85A controls the control voltage Vg in accordance with the temperature of the transistor 64, the present disclosure is not limited to this. The control circuit 85A may control the constant current Id1 or Id2 in accordance with the temperature of the transistor 64.

Furthermore, although, in the above-described examples of control, the control circuit 85A controls the constant current Id1 in accordance with the current amplification factor β of the transistor 64, the present disclosure is not limited to this. The control circuit 85A may control the control voltage Vg or the constant current Id2 in accordance with the current amplification factor β of the transistor 64.

Furthermore, although, in the above-described examples of control, the control circuit 85A controls the constant current Id2 in accordance with the power supply potential Vcc1, the present disclosure is not limited to this. The control circuit 85A may control the control voltage Vg or the constant current Id1 in accordance with the power supply potential Vcc1.

### [Effects]

In comparison with the limiter circuit 22, the limiter circuit 22A can perform control of more finely adjusting the upper limit voltage Vmax and the lower limit voltage Vmin of the high-frequency signal P1, the maximum value I1_max of the current I1, and the maximum value I2_max of the current I2 in accordance with the power supply potential Vcc1, the temperature of the transistor 64, and the current amplification factor β of the transistor 64.

### Third Embodiment

Of components of a limiter circuit according to a third embodiment, components that are the same as those in the other embodiments are denoted by the same reference signs, and a description thereof is omitted.

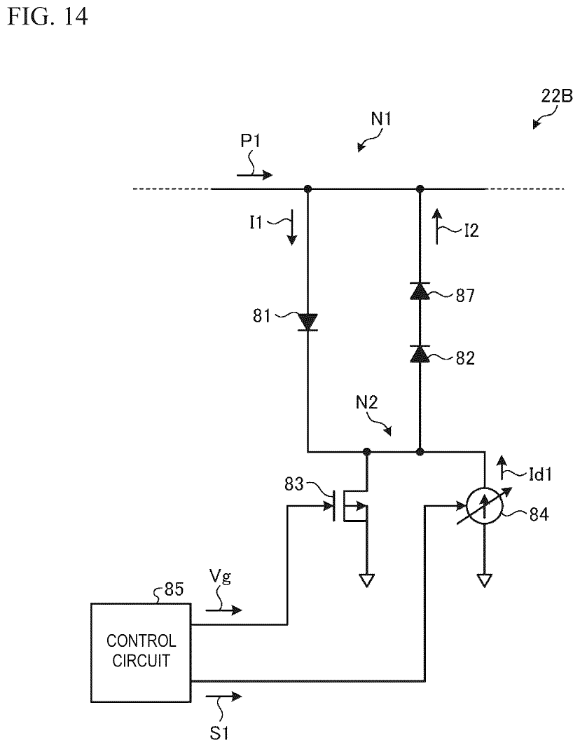

FIG. 14 is a diagram illustrating a configuration of a limiter circuit according to the third embodiment.

In comparison with the limiter circuit 22 (see FIG. 3), a limiter circuit 22B further includes a diode 87.

An anode of the diode 87 is electrically connected to the cathode of the diode 82. A cathode of the diode 87 is electrically connected to the node N1.

Note that, although, in the third embodiment, the limiter circuit 22B includes one diode 81 in the forward direction, the present disclosure is not limited to this. The limiter circuit 22B may include two or more diodes connected in series in the forward direction.

Furthermore, although, in the third embodiment, the limiter circuit 22B includes two diodes 82 and 87 in the reverse direction, the present disclosure is not limited to this. The limiter circuit 22B may include, in the reverse direction, one diode, or three or more diodes connected in series.

Furthermore, the limiter circuit 22B according to the third embodiment may further include the constant current source 86 (see FIG. 10).

### Fourth Embodiment

Of components of a limiter circuit according to a fourth embodiment, components that are the same as those in the other embodiments are denoted by the same reference signs, and a description thereof is omitted.

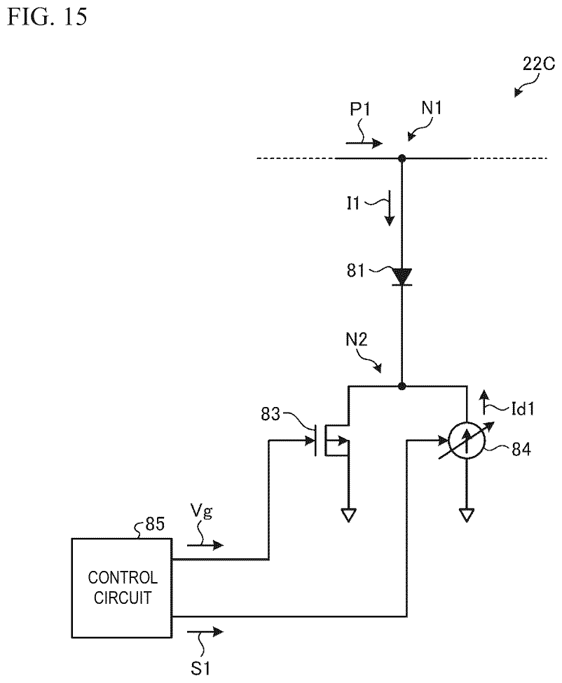

FIG. 15 is a diagram illustrating a configuration of a limiter circuit according to the fourth embodiment.

In comparison with the limiter circuit 22B (see FIG. 14), a limiter circuit 22C includes no diodes 82 and 87. That is, the limiter circuit 22C includes only the diode 81 in the forward direction and includes no diodes 82 and 87 in the reverse direction.

The limiter circuit 22C can adjust the upper limit voltage Vmax and the maximum value I1_max of the current I1.

Note that, although, in the fourth embodiment, the limiter circuit 22C includes one diode 81 in the forward direction, the present disclosure is not limited to this. The limiter circuit 22C may include two or more diodes connected in series in the forward direction.

Furthermore, although, in the fourth embodiment, the limiter circuit 22C includes one diode 81 in the forward direction, the present disclosure is not limited to this. The limiter circuit 22C may include, in the reverse direction, one diode, or two or more diodes connected in series.

Furthermore, the limiter circuit 22C according to the fourth embodiment may further include the constant current source 86 (see FIG. 10).

### Fifth Embodiment

Of components of a limiter circuit according to a fifth embodiment, components that are the same as those in the other embodiments are denoted by the same reference signs, and a description thereof is omitted.

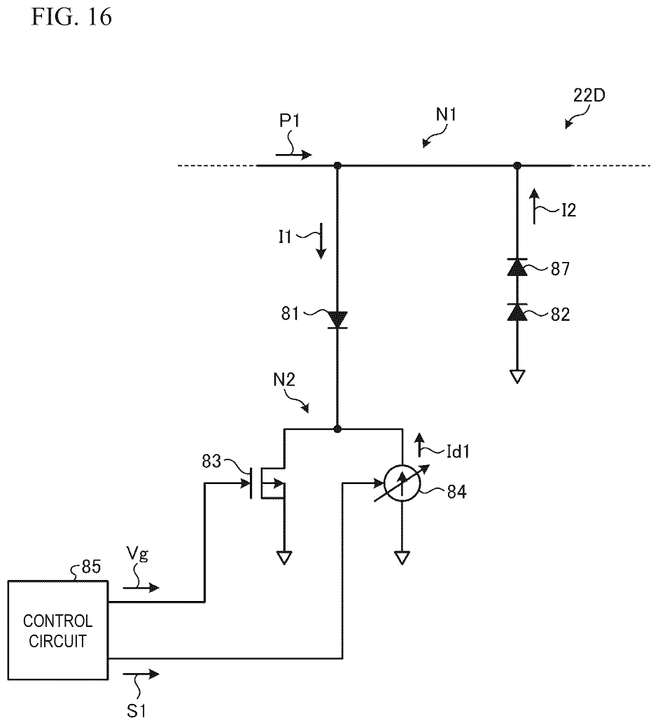

FIG. 16 is a diagram illustrating a configuration of a limiter circuit according to the fifth embodiment.

In comparison with the limiter circuit 22B (see FIG. 14), in a limiter circuit 22D, the anode of the diode 82 is electrically connected to the reference potential.

The limiter circuit 22D can adjust the upper limit voltage Vmax and the maximum value I1_max of the current I1.

The limiter circuit 22D can make the lower limit voltage Vmin and the maximum value I2_max of the current I2 constant.

Note that, although, in the fifth embodiment, the limiter circuit 22D includes one diode 81 in the forward direction, the present disclosure is not limited to this. The limiter circuit 22D may include two or more diodes connected in series in the forward direction.

Furthermore, although, in the fifth embodiment, the limiter circuit 22D includes two diodes 82 and 87 in the reverse direction, the present disclosure is not limited to this. The limiter circuit 22D may include, in the reverse direction, one diode, or three or more diodes connected in series.

Furthermore, the limiter circuit 22D according to the fifth embodiment may further include the constant current source 86 (see FIG. 10).

### Reference Example

Of components of a limiter circuit according to a reference example, components that are the same as those in an embodiment are denoted by the same reference signs, and a description thereof is omitted.

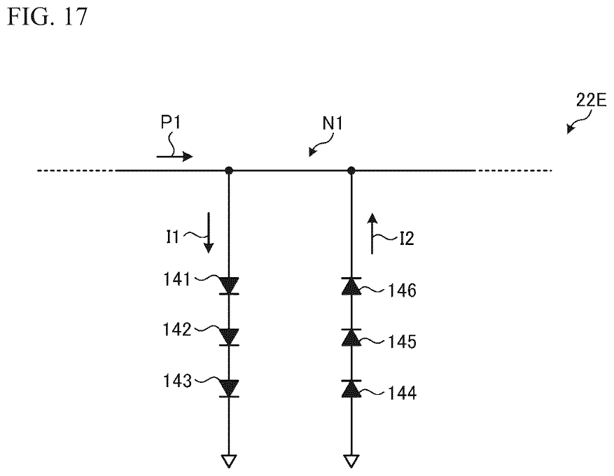

FIG. 17 is a diagram illustrating a configuration of a limiter circuit according to the reference example.

A limiter circuit 22E includes diodes 141 to 146.

An anode of the diode 141 is electrically connected to the node N1. A cathode of the diode 141 is electrically connected to an anode of the diode 142.

A cathode of the diode 142 is electrically connected to an anode of the diode 143.

A cathode of the diode 143 is electrically connected to the reference potential.

An anode of the diode 144 is electrically connected to the reference potential. A cathode of the diode 144 is electrically connected to an anode of the diode 145.

A cathode of the diode 145 is electrically connected to an anode of the diode 146.

A cathode of the diode 146 is electrically connected to the node N1.

Note that, although, in the reference example, the limiter circuit 22E includes three diodes 141 to 143 in the forward direction, the present disclosure is not limited to this. The limiter circuit 22E may include, in the forward direction, one diode, two diodes connected in series, or four or more diodes connected in series.

Furthermore, although, in the reference example, the limiter circuit 22E includes three diodes 144 to 146 in the reverse direction, the present disclosure is not limited to this. The limiter circuit 22E may include, in the reverse direction, one diode, two diodes connected in series, or four or more diodes connected in series.

The above-described embodiments are intended to facilitate understanding of the present disclosure but are not intended for a limited interpretation of the present disclosure. The present disclosure can be changed or improved without necessarily departing from the gist thereof and also encompasses equivalents thereof.

### REFERENCE SIGNS LIST

1 power amplifier circuit
2 first circuit
3 matching network
4 second circuit
5, 6, 7, 8 bias circuit
11, 12, 31, 32 amplifier
22, 22A, 22B, 22C, 22D, 22E limiter circuit
81, 82, 87 diode
83 transistor
84, 86 constant current source
85, 85A control circuit

1. A limiter circuit comprising:
one or more first diodes connected in series, each first diode having an anode electrically connected to a signal line through which a high-frequency signal passes, and a cathode electrically connected to a node;
a transistor having a source-drain path or an emitter-collector path electrically connected between a reference potential and the node, and a gate or a base to which a control voltage or a control current is input; and
a first constant current source configured to output a first constant current to the node.

2. The limiter circuit according to claim 1, further comprising:
one or more second diodes connected in series, each second diode having an anode electrically connected to the node, and a cathode electrically connected to the signal line.

3. The limiter circuit according to claim 1, further comprising:
a control circuit configured to output the control voltage or the control current to the transistor, and to output a first control signal for adjusting the first constant current to the first constant current source.

4. The limiter circuit according to claim 2, further comprising:
a control circuit configured to output the control voltage or the control current to the transistor, and to output a first control signal for adjusting the first constant current to the first constant current source.

5. The limiter circuit according to claim 3, further comprising:
a second constant current source configured to output a second constant current to the node,
wherein the control circuit is further configured to output a second control signal for adjusting the second constant current to the second constant current source.

6. A matching network comprising:
the limiter circuit according to claim 1,
wherein the matching network is configured to match an output impedance of a first circuit and an input impedance of a second circuit,
wherein the first circuit is configured to amplify a high-frequency signal, and
wherein the second circuit is configured to amplify the high-frequency signal amplified by the first circuit.

7. A power amplifier circuit comprising:
a first circuit configured to amplify a high-frequency signal;
a second circuit configured to amplify the high-frequency signal amplified by the first circuit; and
a matching network configured to match an output impedance of the first circuit and an input impedance of the second circuit,
wherein the matching network comprises the limiter circuit according to claim 1.
